(19) United States
(12) Patent Application Publication
(10) Pub. No.: US 2017/0194804 A1
(43) Pub. Date: Jul. 6, 2017

(54) Controlled Drain of Battery at End-of-Life

(71) Applicant: Disruptive Technologies Research AS, Radal (NO)

(72) Inventor: Pål Øyvind Reichelt, Sandvika (NO)

(73) Assignee: Disruptive Technologies Research AS, Radal (NO)

(21) Appl. No.: 15/400,343

(22) Filed: Jan. 6, 2017

Related U.S. Application Data
(60) Provisional application No. 62/275,355, filed on Jan. 6, 2016.

(51) Int. Cl. H02J 7/00; G01R 31/36; G01R 19/165

(52) U.S. Cl. CPC H02J 7/0063; G01R 19/16566; G01R 31/3606; H02J 2007/0067

(57) ABSTRACT

A method of actively draining a power supply of a device circuit is provided. The method may include monitoring an output voltage of the power supply relative to a first lower limit, enabling an active drain circuit to actively drain the power supply when the output voltage falls below the first lower limit, monitoring the output voltage of the power supply relative to a second lower limit that is less than the first lower limit, and disabling the active drain circuit when the output voltage falls below the second lower limit.

### TECHNICAL FIELD

The present disclosure relates generally to battery-operated electronic devices, and more particularly, to systems and methods for actively performing controlled drain of a battery at its end-of-life.

### BACKGROUND

Electronic devices are commonly designed with safeguards designed to protect the circuits within the device from supply voltages that are outside the acceptable range. Such is especially the case with battery-operated devices, which will ultimately encounter low voltage situations as the accompanying battery or other comparable energy source depletes and gradually reaches its end-of-life. Low voltage situations or brownouts can have various adverse effects on the device circuit, and can also cause undesirable failure modes. Correspondingly, battery-operated devices are designed with safeguards, such as lower limits or minimum voltage thresholds, which serve to protect the device against unfavorable failure modes.

In particular, many conventional battery-operated devices are provided with brownout detection features, which monitor for low voltage or brownout conditions, such as those likely associated with a battery at its end-of-life, and cut off power to the device circuit or hold the device circuit in a known and controlled state, such as a reset state, when a brownout condition is detected. However, while in such reset states, it is possible for the output voltage of the battery even at its end-of-life to temporarily rise and return to just barely acceptable levels again. Being unable to distinguish between such an end-of-life battery that is temporarily outputting an acceptable voltage, and a newly replaced battery, a brownout detector will allow the device circuit to attempt to startup again.

Although a temporarily recovered voltage output by an end-of-life battery may be sufficient to restart the device, the battery will ultimately be inadequate to maintain power to the device circuit itself. Moreover, battery-operated devices have much higher active current consumption, or the current used by the device circuit during normal operation, as compared to the reset current consumption, or the current needed to reset or startup the device. Thus, shortly after restarting the device circuit, the brownout detector will need to shut the device down again due to insufficient active current, and this failure loop is subject to repeat for as long as the end-of-life battery is not completely depleted.

The present disclosure is directed at addressing one or more of the deficiencies and disadvantages set forth above. However, it should be appreciated that the solution of any particular problem is not a limitation on the scope of this disclosure or of the attached claims except to the extent expressly noted.

### SUMMARY OF THE DISCLOSURE

In one aspect of the present disclosure, a method of actively draining a power supply of a device circuit is provided. The method may include monitoring an output voltage of the power supply relative to a first lower limit; enabling an active drain circuit to actively drain the power supply when the output voltage falls below the first lower limit; monitoring the output voltage of the power supply relative to a second lower limit that is less than the first lower limit; and disabling the active drain circuit when the output voltage falls below the second lower limit.

In another aspect of the present disclosure, a system for actively draining a power supply of a device circuit is provided. The system may include an active drain circuit configured to actively drain the power supply when enabled, and a latch circuit selectively coupling the active drain circuit to the power supply. The latch circuit may be configured to enable the active drain circuit when an output voltage of the power supply falls below a first lower limit, and disable the active drain circuit when the output voltage falls below a second lower limit that is less than the first lower limit.

In yet another aspect of the present disclosure, a battery-operated device is provided. The battery-operated device may include a battery, a device circuit in electrical communication with the battery and configured to operate the battery-operated device when enabled, an active drain circuit in electrical communication with the battery and configured to actively drain the power supply when enabled, and a latch circuit selectively coupling at least the active drain circuit to the battery. The latch circuit may be configured to enable the active drain circuit when an output voltage of the battery falls below a first lower limit, and disable the active drain circuit when the output voltage falls below a second lower limit that is less than the first lower limit.

These and other aspects and features will be more readily understood when reading the following detailed description in conjunction with the accompanying drawings.

### BRIEF DESCRIPTION OF THE DRAWINGS

FIG. 1 is a diagrammatic view of one exemplary battery-operated device employing an active drain system of the present disclosure;

FIG. 2 is a diagrammatic view of exemplary states of operation of the active drain system of the present disclosure;

FIG. 3 is a qualitative graphical view of one exemplary set of thresholds to be used in operating the active drain system of the present disclosure; and

FIG. 4 is a flow diagram of one exemplary scheme or method of actively performing a controlled drain of an end-of-life battery.

While the following detailed description is given with respect to certain illustrative embodiments, it is to be understood that such embodiments are not to be construed as limiting, but rather the present disclosure is entitled to a scope of protection consistent with all embodiments, modifications, alternative constructions, and equivalents thereto.

### DETAILED DESCRIPTION

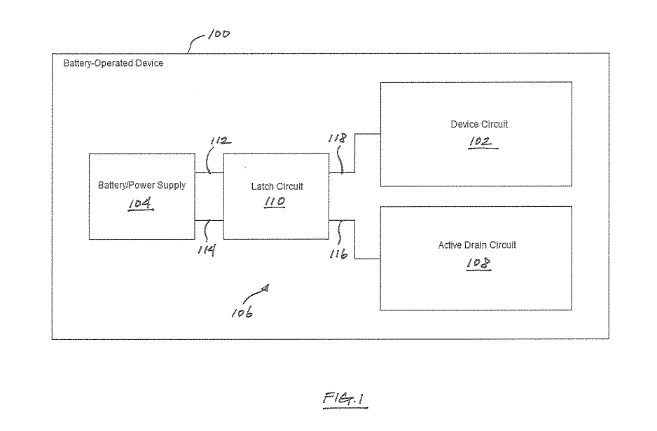

Referring to FIG. 1, one exemplary embodiment of a battery-operated device 100 is diagrammatically provided. As shown, the battery-operated device 100, in its simplest form, may generally include a device circuit 102 and a battery 104. More specifically, the battery-operated device 100, as well as the device circuit 102, may represent any electronic device that is designed for mobile or portable use, and configured to operate from a direct current (DC) power source. Correspondingly, the battery 104 may represent any suitable chargeable or rechargeable DC power supply that can be removably coupled to the battery-operated device 100 and/or the device circuit 102. Furthermore, although only one configuration is shown in FIG. 1, it will be understood that the battery-operated device 100 may be composed of a plurality of device circuits 102 and/or a plurality of batteries 104, and/or be arranged in other configurations than shown.

The battery-operated device 100 in FIG. 1 may additionally be provided with an active drain system 106 incorporated therein. More specifically, the active drain system 106 may include an active drain circuit 108, and a latch circuit 110 selectively coupling either the device circuit 102 or the active drain circuit 108 to the battery 104. For example, when enabled, the device circuit 102 may be placed in electrical communication with the battery 104 and configured to operate the battery-operated device 100. Alternatively, when the active drain circuit 108 is enabled, the active drain circuit 108 may be placed in electrical communication with the battery 104 and configured to actively drain the battery 104. In particular, the active drain circuit 108 may comprise any combination of commonly known circuit elements, such as resistive elements, that can be used to completely or substantially completely deplete a battery 104 that is at its end-of-life.

Still referring to FIG. 1, the latch circuit 110 may be representative of one or more electronic latches, such as set/reset (SR) latches, or any other comparable circuit that is capable of being set and remain set until a sufficient reset is received. In the example embodiment of FIG. 1, for example, the latch circuit 110 may represent a logic circuit including a first input 112 that is configured to set the latch circuit 110, and a second input 114 that is configured to reset the latch circuit 110. The latch circuit 110 may also include a first output 116 that is configured to correspond to the set or reset signal, and a second output 118 that is a direct logic inverse of the first output 116. As shown, for example, both of the first and second inputs 112, 114 may be coupled to the battery 104, while the first output 116 is coupled to the device circuit 102 and the second output 118 is coupled to the active drain circuit 108. Moreover, the latch circuit 110 may be configured such that only one of the device circuit 102 or the active drain circuit 108 is coupled to the battery 104 at a time.

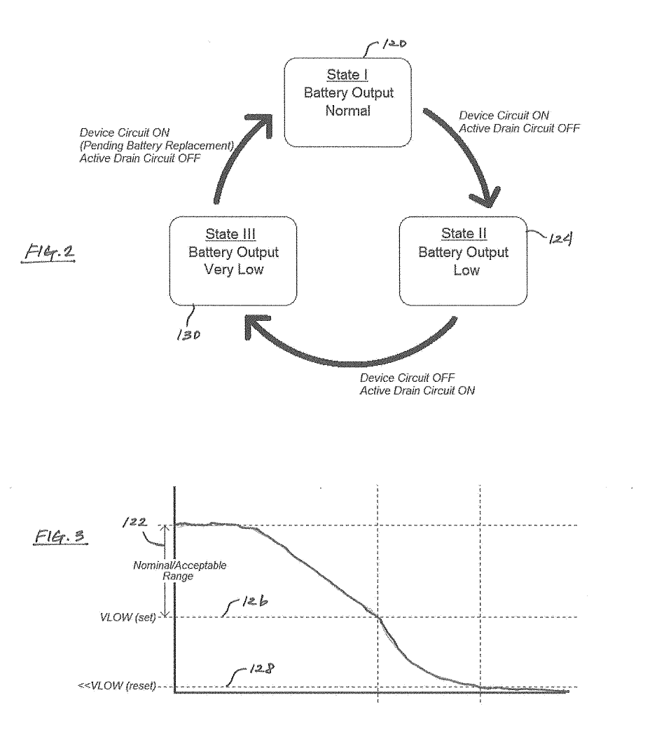

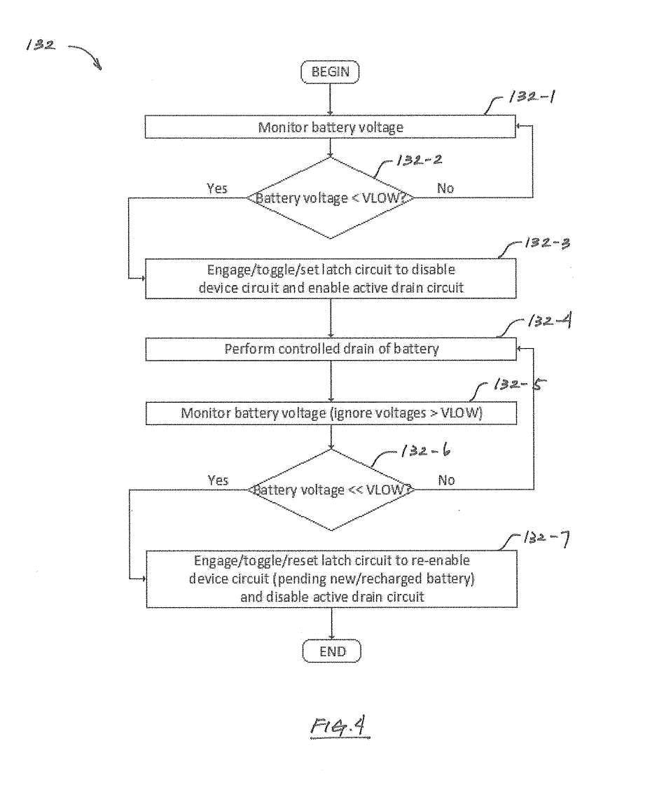

The manner by which the latch circuit 110 of FIG. 1 is set or reset can be explained with reference to the state diagrams illustrated in FIG. 2. In a first state 120, for instance, the battery 104 may not be near its end-of-life and outputting nominal output voltage, or voltage within an acceptable range 122 for operating the device circuit 102 as qualitatively illustrated in FIG. 3. During the first state 120, the latch circuit 110 may be configured to enable the device circuit 102 but disable the active drain circuit 108. The active drain system 106 may enter a second state 124 when the battery 104 nears its end-of-life and its output voltage falls to a first lower limit 126 as shown in FIG. 3. Correspondingly, the lower output voltage may signal to the active drain system 106 to protect the device circuit 102 and to actively drain the battery 104 to prevent any unwanted restarting. Moreover, the lower output voltage during the second state 124 may cause the latch circuit 110 to be set, and thereby cause the latch circuit 110 to disable the device circuit 102 and enable the active drain circuit 108.

During the second state 124 of FIG. 2, the active drain circuit 108 may actively drain the battery 104 while maintaining the device circuit 102 in the disabled state until the battery 104 is completely drained. The disabled state may be a state within which the device circuit 102 is decoupled from power, held in a known and controlled reset state, or any other comparable means of effectively disabling the device circuit 102. The latch circuit 110 may be configured such that, once set, the device circuit 102 is prevented from being re-enabled until a sufficient reset condition is satisfied. In other words, the latch circuit 110 during the second state 124 prevents the device circuit 102 from restarting even if the output voltage of the battery 104 is, by chance, temporarily restored to within acceptable levels 122. The active drain circuit 108 may continue draining the battery 104 until the output voltage of the battery 104 reaches a second lower limit 128 that is significantly less than the first lower limit 126 as again qualitatively shown in FIG. 3. The second lower limit 128 may represent an output voltage low enough to characterize the battery 104 as completely discharged and at no risk of undesirably restarting the device circuit 102.

Once the output voltage of the battery 104 reaches the second lower limit 128, the active drain system 106 may enter a third state 130 as shown in FIG. 2. In the third state 130, the output voltage may be configured to reset the latch circuit 110, which in turn, may cause the latch circuit 110 to disable the active drain circuit 108 and re-enable the device circuit 102. In particular, although the device circuit 102 may be re-enabled during the third state 130, the device circuit 102 will not be able to restart until the battery 104 has been replaced or otherwise sufficiently renewed. Once the battery 104 is replaced or sufficient renewed, the active drain system 106 may return to the first state 120 and repeat accordingly. Although the embodiments of FIGS. 2 and 3 depict one example of how the active drain system 106 may operate, and one set of limits by which the latch circuit 110 may be configured to operate, it will be understood that other arrangements and modifications are certainly possible without departing from the scope of the appended claims.

Turning now to FIG. 4, one exemplary method 132 of actively draining a power supply or battery 104 is provided. In particular, one or more of the processes of the method 132 may be implemented using one or more of algorithms, instructions, logic operations, and the like, and/or using digital circuitry, analog circuitry, and/or other electrical hardware. Moreover, the method 132 may be implemented using, for example, the latch circuit 110 and the active drain circuit 108 of the active drain system 106 schematically illustrated in FIG. 1. As shown in FIG. 4, the method 132 in block 132-1 may initially monitor the output voltage of the battery 104 to determine when the battery 104 is nearing or at its end-of-life. More specifically, the method 132 in block 132-2 may detect when the output voltage of the battery 104 falls below a first lower limit 126, or voltage threshold VLOW, which may represent voltage that is too low to adequately supply power to the device circuit 102, and at which point the battery 104 should be deemed to be failing.

If the output voltage of the battery 104 remains to be greater than the first lower limit 126, the method 132 in FIG. 4 may deem the battery 104 as still healthy and return to block 132-1 to continue monitoring for signs of a failing battery 104. If, however, the output voltage of the battery 104 falls below the first lower limit 126, the method 132 may proceed to block 132-3. In block 132-3, the method 132 may disable the device circuit 102 or enter a known and controlled state, such as a reset state, and enable the active drain circuit 108, for example, by engaging, toggling or setting the latch circuit 110 of FIG. 1. By disabling the device circuit 102 or holding the device circuit 102 in such a reset state, the method 132 is able to protect the device circuit 102 from failure modes of operation until the battery 104 is completely replaced or restored. Additionally, by enabling the active drain circuit 108, the method 132, such as in block 132-4, is able to actively drain the end-of-life battery 104 further, so as to prevent inadvertent restarting and related failure loops.

Furthermore, while the battery 104 is being actively drained, the method 132 in block 132-5 of FIG. 4 may also monitor the output voltage of the battery 104 to determine whether the battery 104 has been sufficiently drained. Notably, during this stage, the method 132 may be specifically designed to disregard any increases in output voltage, even voltages exceeding the first lower limit 126, for the purposes of preventing inadvertent restarts or failure loops. As shown in block 132-6, the method 132 may detect only for when the output voltage falls to a second lower limit 128, or a voltage threshold that is significantly less than VLOW. The second lower limit 128 may be representative of when the battery 104 has been sufficiently drained and where there is no risk of inadvertently restarting or initiating failure loops. If the output voltage of the battery 104 remains to be less than the first lower limit 126 but still greater than the second lower limit 128, the method 132 may deem that the battery 104 is still being drained and continue monitoring the output voltage per block 132-5.

If, however, the method 132 in block 132-6 of FIG. 4 determines that the output voltage of the battery 104 has reached or falls below the second lower limit 128, the method 132 may deem the battery 104 as being completely drained, depleted, and at no risk of inadvertently restarting the device circuit 102. Correspondingly, the method 132 in block 132-7 may disable the active drain circuit 108 and re-enable the device circuit 102. The method 132 may disable the active drain circuit 108 and enable the device circuit 102, for example, by engaging, toggling or resetting the latch circuit 110 of FIG. 1. Notably, although the device circuit 102 is re-enabled, it will not power on until the battery 104 has been replaced or completely restored. Once the battery 104 has been replaced or restored, the method 132 may return to block 132-1 and repeat the processes discussed above.

It will be noted that the method 132 depicted in FIG. 4, or the monitoring processes thereof, may be performed continuously or periodically at predefined intervals. Furthermore, although the method 132 is illustrated in one possible sequence of processes, it will be understood that any two or more of the processes shown may be performed simultaneously or in other sequences without departing from the scope of the appended claims. Also, while only one arrangement of processes are shown in FIG. 4, it will be understood that other arrangements or variations may be similarly employed. Other arrangements, for example, may modify, merge, omit and/or add to any of the blocks shown in FIG. 4 and still provide comparable results. It will be appreciated that while only certain embodiments have been set forth for the purposes of illustration, alternatives and modifications will be apparent from the above description to those skilled in the art. These and other alternatives are considered equivalents and within the spirit and scope of this disclosure and the appended claims.

What is claimed is:

1. A method of actively draining a power supply of a device circuit, the method comprising:
monitoring an output voltage of the power supply relative to a first lower limit;
enabling an active drain circuit to actively drain the power supply when the output voltage falls below the first lower limit;
monitoring the output voltage of the power supply relative to a second lower limit that is less than the first lower limit; and
disabling the active drain circuit when the output voltage falls below the second lower limit.

2. The method of claim 1, wherein the enabling and disabling of the active drain circuit is performed using a latch circuit coupled to one or more of the device circuit and the active drain circuit.

3. The method of claim 2, wherein enabling the active drain circuit also disables the device circuit, and disabling the active drain circuit also re-enables the device circuit.

4. The method of claim 2, wherein the latch circuit enables the active drain circuit when set, and disables the active drain circuit when reset.

5. The method of claim 1, wherein the active drain circuit is enabled when the output voltage at least temporarily falls below the first lower limit, and maintained enabled until the output voltage falls below the second lower limit.

6. The method of claim 5, wherein the device circuit is disabled when the output voltage at least temporarily falls below the first lower limit, and maintained disabled until the output voltage falls below the second lower limit.

7. A system for actively draining a power supply of a device circuit, the system comprising:
an active drain circuit configured to actively drain the power supply when enabled; and
a latch circuit selectively coupling the active drain circuit to the power supply, the latch circuit being configured to enable the active drain circuit when an output voltage of the power supply falls below a first lower limit, and disable the active drain circuit when the output voltage falls below a second lower limit that is less than the first lower limit.

8. The system of claim 7, wherein the latch circuit is electrically disposed between each of the power supply, the device circuit, and the active drain circuit.

9. The system of claim 7, wherein the latch circuit is configured to selectively couple the power supply to one of the device circuit and the active drain circuit.

10. The system of claim 7, wherein the latch circuit is configured to disable the device circuit when the active drain circuit is enabled, and re-enable the device circuit when the active drain circuit is disabled.

11. The system of claim 7, wherein the latch circuit is configured such that setting the latch circuit enables the active drain circuit, and resetting the latch circuit disables the active drain circuit.

12. The system of claim 7, wherein the latch circuit is configured to enable the active drain circuit when the output voltage at least temporarily falls below the first lower limit, and maintain the active drain circuit in the enabled state until the output voltage falls below the second lower limit.

13. The system of claim 7, wherein the latch circuit is configured to disable the device circuit when the output voltage at least temporarily falls below the first lower limit, and maintain the device circuit in the disabled state until the output voltage falls below the second lower limit.

14. A battery-operated device, comprising:
a battery;
a device circuit in electrical communication with the battery and configured to operate the battery-operated device when enabled;
an active drain circuit in electrical communication with the battery and configured to actively drain the power supply when enabled; and
a latch circuit selectively coupling at least the active drain circuit to the battery, the latch circuit being configured to enable the active drain circuit when an output voltage of the battery falls below a first lower limit, and disable the active drain circuit when the output voltage falls below a second lower limit that is less than the first lower limit.

15. The battery-operated device of claim 14, wherein the battery is one of a rechargeable battery and a replaceable battery.

16. The battery-operated device of claim 14, wherein the latch circuit is configured to selectively couple the battery to one of the device circuit and the active drain circuit.

17. The battery-operated device of claim 14, wherein the latch circuit is configured to disable the device circuit when the active drain circuit is enabled, and re-enable the device circuit when the active drain circuit is disabled.

18. The battery-operated device of claim 14, wherein the latch circuit is configured to enable the active drain circuit when the output voltage at least temporarily falls below the first lower limit, and maintain the active drain circuit in the enabled state until the output voltage falls below the second lower limit.

19. The battery-operated device of claim 14, wherein the latch circuit is configured to disable the device circuit when the output voltage at least temporarily falls below the first lower limit, and maintain the device circuit in the disabled state until the output voltage falls below the second lower limit.

20. The battery-operated device of claim 14, wherein the latch circuit is configured such that, once the device circuit has been disabled, the output voltage is not supplied to the device circuit until the battery has been completely replenished.
